(19) United States
(12) Patent Application Publication
(10) Pub. No.: US 2012/0174572 A1
(43) Pub. Date: Jul. 12, 2012

(54) METHOD FOR MECHANICAL AND ELECTRICAL INTEGRATION OF SMA WIRES TO MICROSYSTEMS

(76) Inventors: Donato Clausi, Heverlee (BE); Jan Piers, Oud-Heverlee (BE); Dominiek Reynaerts, Oud-Heverlee (BE); Stefan Braun, Nurtingen (DE); Henrik Gradin, Sollentuna (SE); Wouter van der Wijngaart, Sollentuna (SE)

(21) Appl. No.: 13/346,039

(22) Filed: Jan. 9, 2012

Related U.S. Application Data
(60) Provisional application No. 61/460,989, filed on Jan. 10, 2011.

(51) Int. Cl. F03G 7/06; H05K 13/04

(52) U.S. Cl. 60/527; 29/854

(57) ABSTRACT

The present invention relates to methods for the batch fixation and electrical connection of pre-strained SMA wires on a microstructured substrate using electroplating, providing high bond strength and electrical connections in one processing step. The integration process here developed relies on conventional micro machining techniques and it provides an efficient solution to some problems that have hindered the widespread diffusion of bulk SMA to MEMS, such as the lack of cost-efficient integration methods of bulk SMA and the difficult electrical contacting of the actuator material at small scale. Also disclosed herein is a Joule-heated SMA wire actuator on silicon MEMS.

The benefit of U.S. provisional application No. 61/460,989 filed on Jan. 10, 2011 is claimed and the application is incorporated herein by reference.

### FIELD OF THE INVENTION

The present invention relates generally to the field of microsystems, and more particularly to micro- or meso-scale devices comprising shape memory alloy (SMA) wires which can be actuated by Joule heating and methods for producing the same.

### BACKGROUND ART

Shape memory alloy (SMA) materials exhibit reversible solid state transformation between two characteristic phases: relatively stiff austenite at high temperatures, and relatively ductile martensite at low temperatures. The shape memory effect (SME) refers to the ability of the material, initially deformed in its low-temperature phase, to recover its original shape upon heating to its high temperature phase. Partially constraining the shape recovery during heating results in the generation of work. SMA-based actuators mostly utilize the one-way effect, thus an external force (cold-state restore or bias mechanism) is needed to deform the material in martensitic phase in order to achieve cyclical behavior as described by Duerig et al. in Engineering Aspects of Shape Memory Alloys. London, U.K.: Butterworth-Heinemann Ltd., 1990. Hence, the SMA is typically coupled with an additional mechanical element, which can be either a bias spring or another SMA (“antagonistic design”) as described by Bellouard in “Shape memory alloys for microsystems: A review from a material research perspective,” Mater. Sci. Eng. A, vol. 481/482, pp. 582-589, 2008. The force per unit surface generated by these actuators can be in the hundreds of MPa, higher than for any other actuator type. In terms of work density SMAs outperform other active materials at the micro-scale, exceeding the work production per unit volume of other principles by at least an order of magnitude as described by van Humbeeck in “Shape memory alloys: A material and a technology,”Adv. Eng Mater., vol. 3, no. 11, pp. 837-850, November, 2001. Furthermore, their surface to volume ratio increases with miniaturization, which results in enhanced cooling and higher bandwidth. Miniaturized actuators benefit also from a higher electrical resistance, thus requiring lower current when triggered by direct electrical heating.

Despite its favorable characteristics, the successful use of SMA in micro-electro-mechanical systems (MEMS) has been hindered, mainly because of the lack of cost-efficient and robust integration methods. With this respect, three main technical challenges are to be solved: first, the SMA has to form a strong mechanical bond to the target structures to withstand the high forces and the high temperatures generated upon repeated actuation; second, mechanical and electrical connections should preferably be batch-manufactured using standard micromachining techniques, to achieve an overall cost reduction. Third, a bias mechanism is required to deform the SMA in martensitic state to achieve cyclic actuation. It is often difficult to implement this bias mechanism at the microscale.

The standard integration method of SMA materials to microsystems is based on sputter deposition of thin TiNi films on target MEMS structures, which is inherently a batch-compatible technique. Devices fabricated as such can be actuated by either direct or indirect heating as described by Krulevitch et al. in “Thin film shape memory alloy microactuators,” J. Microelectromech. Syst., vol. 5, no. 4, pp. 270-82, December 1996, and the bias spring is provided by the built-in film stress. One major problem with this approach is the reliable fabrication of TiNi thin films with reproducible transformation temperatures and transformation strains, as these parameters are very sensitive to compositional variation. Since the Ti and Ni constituents in alloy sputtering targets have different sputtering yields during deposition, a co-sputtering procedure has been published which uses an alloy TiNi target and an elemental Ti target to reliably achieve stoichiometric SMA films as described by Hahm et al. in “Fully microfabricated, silicon spring biased, shape memory actuated microvalve,” in Proc. Solid-State Sens. Actuator Workshop, 2000, pp. 230-233. However, for TiNi-based films sputtering is mostly feasible for thicknesses less than 10 μm as described by Miyazaki et al. in “Development of high-speed microactuators utilizing sputter-deposited TiNi-base shape memory alloy thin films,” in Proc. Actuators, Bremen, Germany, 2008, pp. 372-377, thus resulting in limited mechanical robustness of structures actuated by SMA films.

In the hybrid integration method, the SMA components and the MEMS structure are fabricated separately and then assembled on a per-device level. The bias spring is provided by a mechanical obstruction, which deforms the SMA during the assembly of the SMA element and the MEMS structure as described by Strobanek et al. in “Stress-optimized shape memory microvalves,” in Proc. IEEE MEMS, 1997, pp. 256-261. This approach features the advantage of using bulk SMA, which is commercially available in a wide thickness range and therefore allows for adjustable mechanical robustness and reduced material cost. However, electrical connections are difficult to realize in miniature devices, and the required per-device assembly results in high component costs.

Monolithic SMA actuators integrate both the actuating function and the restore mechanism in the same piece of material. Their material grain structure is changed by local annealing, either by direct Joule heating or by laser heating as described by Bellouard et al. in “Local annealing of complex mechanical devices: A new approach for developing monolithic micro-devices,” Mater. Sci., Eng. A, vol. 273-275, pp. 795-798, December 1999, to confer the desired functional properties to the targeted area: the annealed regions exhibit shape memory effect (SME), whereas the non-annealed parts display an elastic behavior and serve as bias spring. This approach allows avoiding assembly to a certain extent and it is not limited to out-of-plane bending actuators; however, it uses a vast amount of shape memory material while exploiting the SME only for small portions of it, thus resulting into a lower efficiency.

We reported on the wafer-level integration of SMA wires to silicon MEMS using adhesive bonding in “Microactuation utilizing wafer-level integrated SMA wires,” in Proc. IEEE MEMS, 2009, pp. 1067-1070. Compared to other SMA actuators that are available at the microscale, the utilization of the prestrained TIN™ wires in combination with single-crystalline silicon cantilevers presents considerable advantages in terms of work efficiency. However, this approach has the disadvantage that it requires external heating for actuation, and that the adhesive Si-to-SMA wire anchor was the point of failure due to the large stresses in the SMA during shape recovery.

In “Bending, torsional and extending active catheter assembled using electroplating”, in Proc. MEMS 2000, pp. 181-186 by Haga et al., a method is presented for fabricating active catheters for medical applications. Bending control of the catheter is achieved by means of three electrically activated SMA coil actuators fixed between a stainless steel liner coil and an inner tube that is used for injection or suction of fluids or for insertion of micro tools. Either torsional, extending or stiffness control of the actuator is performed through a SMA coil fixed coaxially inside the liner coil, depending on the deformation imposed to the SMA coil prior insertion of the catheter in the blood vessel. The stainless steel liner coil serves as bias mechanism for the SMA actuators and as a common ground during electric actuation.

The fabrication method comprises electrodeposition of acrylic resin or parylene evaporation to electrically insulate the SMA coils and the liner coil. The insulator is locally removed using YAG laser in selected locations, where nickel is subsequently electroplated. Mechanical connections between the deposited nickel on the liner coil and the SMA coils are formed by electrodeposition of acrylic resin. The electric connections are formed by a second local removal of the insulator on the SMA coil and the liner coil using a YAG laser and then by electroplating nickel.

This method has the disadvantage that the fabrication process involves several steps to form the mechanical and electrical connections, and it requires a YAG laser to remove the insulator in the desired locations. Furthermore, the fabrication of the catheter relies on manual assembly of its components and does not allow high volume production of such device.

In another report entitled “Frequency-controlled wireless shape-memory-alloy microactutors integrated using an electroplating bonding process”, Sensors and Actuators A: Physical, pp. 363-372 by Mohamed Ali et al. a frequency-controlled wireless SMA gripper is presented which is mechanically connected to a polyimide (PI) film by copper electroplating. The device is passively controlled through RF power transfer to a resonant heater circuit on the PI film, with which the SMA actuator is coupled.

The gripper structure is formed by micro-electro-discharge-machining (μEDM) of a Ti—Ni sheet, and the outer sidewalls of its two beams are coated with a compressive SiO₂ layer that provides the cold-state restore of the actuator. Copper plating is used to mechanically connect the SMA bonding pad to a capacitor electrode on the PI substrate through holes formed by μEDM. The SMA gripper is actuated by the heat transferred to it from the LC coil.

This method uses a SMA sheet instead of SMA wires for the actuator, which results in lower energy efficiency. Furthermore, the production process requires several machining steps by μEDM of the SMA sheet to form the gripper beams and the holes for bonding, thus increasing the overall cost of the device.

### SUMMARY OF THE INVENTION

It is an object of the present invention to provide robust devices comprising shape memory alloy (SMA) wires which can be actuated by Joule heating and methods for producing the same.

It is an advantage of embodiments according to the present invention that a cost-efficient manufacturing process is obtained, as the provision of some components can be provided in or during one and the same process.

It is an advantage of embodiments according to the present invention that a strong mechanical bond can be obtained of the SMA wires to the target structure, which allows withstanding high forces and high temperature.

It is an advantage of embodiments according to the present invention that the mechanical connection can resist large stresses in the SMA wire during shape recovery.

It is an advantage of embodiments according to the present invention that actuation can be performed through Joule heating, thus avoiding the need to use external heating for actuation.

It is an advantage of embodiments according to the present invention that mechanical and electrical connections can be performed during the same process. It is an advantage of embodiments according to the present invention that the method allows high volume production of the devices.

It is an advantage of embodiments according to the present invention that the number of processing steps required for manufacturing of the devices can be limited.

The above object can be obtained by a method and system according to embodiments of the present invention. The present invention relates to a method for producing a device comprising at least one SMA wire capable of changing its length when heated, the method comprising providing a target substrate, positioning the at least one SMA wire in the vicinity of the target substrate, and mechanically connecting the at least one SMA wire to the target substrate by a metal plating process and providing, in the same metal plating process, an electrical connection pad to the SMA wire, such that the electrical contact pad is electrically insulated from the target substrate.

The target substrate may comprise an array of structures formed by at least one bias mechanism. Positioning the at least one SMA wire in the vicinity of the target substrate may be depositing the at least one SMA wire onto the target substrate. The at least one SMA wire may be a multiple of SMA wires. The positioning may be performed in a single step.

It is an advantage of embodiments of the present invention that by using metal plating, the at least one SMA wire can be mechanically connected to a substrate, while at the same time providing an electrical contact to the SMA wire, thereby avoiding the need for a separate step for making an electrical connection to the SMA wire. The mechanical connection by metal plating may be sufficiently strong for allowing the SMA wire to deform without loosening from the substrate when heated, while the electrical contact may be used for providing an electrical current to the SMA wire for heating it.

It is an advantage of embodiments of the present invention that metal plating is a cost-efficient and robust integration method, which may be applied at multiple locations on the substrate at the same time. The latter is especially useful when making an array of devices, each device comprising at least one SMA wire.

It is an advantage of embodiments of the present invention that by using a prefabricated SMA wire, which is commercially available in various thicknesses, the SMA wire has predictable properties, such as e.g. transformation temperature and transformation strain.

The mechanical connection and the electrical connection pad may be distinct features processed in the same metal plating process.

The metal plating may be performed such that the at least one SMA wire is completely surrounded by plated metal over at least a part of its length. By completely surrounding the SMA wire, robust mechanical anchor points are provided to the SMA wire, with a minimal risk of coming loose. And in the same metal-plating step, an easy accessible electrical contact is provided to the SMA wire. The latter is especially useful for SMA wires that are to be heated by Joule-heating, i.e. heat produced by a current when flowing through an electrical resistance, in this case of the SMA wire.

The target substrate may comprise one or more of a silicon wafer, a metal sheet, a polymer film or a multi-layer substrate. It is an advantage of embodiments of the present invention that the method can be applied to a wide variety of substrates, which may be electrically conductive, electrically insulating, or semi-conductive. This makes the method very versatile.

According to embodiments of the present invention, the target substrate may have a thickness between 0.01 mm and 2 mm, although embodiments of the present invention are not limited thereby.

The mechanical connection obtained by the mechanically connecting and the electrical connection pad may be positioned at distinct locations.

The metal plating process may be an electroplating process.

The electroplating process may comprise applying one or more of the group of nickel, copper, thin, silver or gold. It is an advantage of embodiments of the present invention that these metals are very suitable for electro-plating, and provide robust mechanical connections to the substrate, and “good” electrical connections to the SMA wire.

The target substrate may comprise an electrically conductive or semi-conductor material, and the method further may comprise applying an insulating layer on top of the target substrate for electrically separating the SMA wire from the target substrate, and depositing a conductive layer on top of the insulating layer for providing a seed layer for allowing electroplating.

It is an advantage of embodiments according to the present invention that electroplating can be used, while an electrical isolation from the substrate is obtained. This may be desirable in devices containing other elements (e.g. circuits) than the SMA wire, whereby the SMA wire should be electrically separated from the other elements. This may for example be especially the case for a Silicon substrate, where an electrical circuit and a MEMS structure comprising the SMA wire can be embedded in the same device.

The target substrate may be a silicon substrate, and wherein said applying an insulating layer comprises applying a SiO₂ layer on the silicon substrate, and said depositing a conductive layer comprises depositing a nickel layer on top of the SiO₂ layer.

It is an advantage of embodiments of the present invention that an SMA wire can be connected to a Silicon substrate in a very robust way, while at the same time providing an easy accessible electrical connection to the SMA wire. This is especially advantageous in devices where relatively large forces are exerted upon the SMA wire, so that the risk of loosening reduces or can be brought to 0.

The metal plating process may be an electroless plating process. The electroless plating process may comprise applying one or more of the group of nickel, copper, silver or gold.

The at least one SMA wire may be a pre-strained SMA wire. It is an advantage of embodiments according to the present invention that by using a pre-stretched SMA wire, the “learning” of the SMA material after being connected to the substrate can be avoided, and the characteristics of the SMA wire are predetermined. A pre-stretched SMA wire is particularly useful for making normal-closed micro-valves, which can be opened by heating the SMA wire.

The pre-strained SMA wire may be pre-strained such that its length is 1% to 8% shorter in a heated condition as compared to an unheated condition.

The at least one SMA wire may comprise an alloy selected from the group consisting of nickel-titanium, copper-aluminum-nickel or copper-zinc-aluminum.

It is an advantage of embodiments according to the present invention that various materials may be used for the SMA wire, making the method widely applicable.

Said positioning of the at least one SMA wire may comprise bringing the SMA wire in the vicinity of the target substrate and temporarily holding the SMA wire using an adhesive anchor.

It is an advantage of embodiments according to the present invention that a “direct” method can be applied, whereby the SMA wire is temporarily mounted on the target substrate without needing a carrier substrate. The adhesive anchor then only needs to hold the SMA wire temporarily until the metal plating is done, thereafter the mechanical anchor takes over. The adhesive anchor does not need to resist high forces as in the metal plating step, the forces exerted on the SMA wire and the substrate are negligible. Said positioning therefore may be directly depositing the at least one SMA wire on the target substrate.

It is an advantage of some embodiments according to the present invention that an “indirect” method can be applied, whereby the SMA wire is first mounted to a carrier substrate, and then transferred to the target substrate. Said positioning of the at least one SMA wire may therefore comprise bringing the SMA wire in the vicinity of a carrier substrate, and thereafter transferring the SMA wire to the target substrate. The at least one SMA wire may first be embedded in polymer and then be transferred to the target substrate. It may be advantageous of embodiments according to the present invention that the SMA-wires can easily fabricated in a dedicated facility and transferred using a carrier substrate. The latter allows that assembly, the standard processes can be used.

The at least one SMA wire may have a circular cross-section. The at least one SMA wire may have a flat cross-section. The at least one SMA wire may have an elliptical cross-section.

The device may comprise at least a first and a second SMA wire, and the step of mechanically connecting and providing an electrical connection pad may be performed by providing two separate electrical contact pads at first positions of the first and second SMA wire, and by providing a single metal pad for interconnecting the first and second SMA wires at second positions thereof, distinct from the first positions.

It is an advantage of embodiments of the present invention that the metal at the first positions can be used as electrical contact pads for applying a current through the first and second SMA wires for heating the SMA wires by Joule heating.

It is an advantage of embodiments of the present invention that the metal plating process allows that in a single step the two wires can be mechanically connected to the substrate, and that at the same time contact pads can be provided to each of the wires, and that at the same time the SMA wires can be connected to each other, e.g. at their other ends.

It is an advantage of embodiments according to the present invention that the obtained mechanical structure is more stable. This can for example be advantage when used as a micro-actuator.

The device to be produced may comprise a micro-actuator, the micro-actuator comprising the at least one SMA wire and further comprising an elastic element for restoring the length of the SMA-wire when the SMA wire is not heated, wherein in the method, said providing a target substrate may comprise providing a target substrate having at least one elastic element, said positioning may comprise positioning the at least one SMA wire in the vicinity of the elastic element, and said mechanically connecting and providing an electrical connection pad may comprise performing metal plating for mechanically connecting the at least one SMA wire to the target substrate at a first position, and to the elastic element at a second position, different from the first position.

The elastic element may e.g. be a cantilever provided in a Silicon substrate, having a fixed anchor for connecting it to the substrate at one end thereof, and a movable anchor at another end thereof. Such a structure may e.g. be useful as part of a micro-valve.

Said positioning may comprise positioning the SMA wire eccentrically with respect to the elastic element for allowing out-of-plane actuation.

The method may be for producing a plurality of devices, each comprising at least one SMA wire, wherein said positioning may comprise the positioning of a plurality of SMA wires in the vicinity of the target substrate, and said mechanically connecting and providing an electrical connection pad may comprise performing metal plating for mechanically connecting each of the plurality of SMA wires at multiple locations to the target substrate simultaneously, and for providing in the same metal plating step a plurality of electrical contact pad to each of the SMA wires, the electrical contact pads being electrically isolated from the target substrate.

In this way, a plurality of devices (e.g. micro-actuators) can be produced in a very efficient way. In particular, a single metal plating step can be used for making all mechanical “anchors” and “electrical contact pads” of the entire substrate. This is especially efficient, compared to for example the use of adhesive, where each and every individual connection needs to be done separately.

The present invention also relates to a device comprising at least one SMA wire capable of changing length when heated, the device comprising a target substrate, the at least one SMA wire being mechanically connected to the target substrate by a metal plated anchor and comprising a metal plated electrical connection pad for electrically connecting to the SMA wire. The metal plated anchor for mechanically connecting and the metal plated electrical connection pad can be made during the same metal plating process. The metal plated anchor and the metal plated electrical connection pad may be the same metal plated anchor, whereby the metal plated anchor may be provided such that it is electrically isolated from the sheet-like target substrate.

A device with an electrical isolation between the SMA wire and the substrate according to embodiments of the present invention has the advantage that the SMA-wire can be heated by Joule heating, without having to use the substrate as a conductor. This allows the substrate to comprise other devices (e.g. control circuitry), that is not affected by the current for heating the SMA-wire. The device may comprise a micro-actuator, the micro-actuator comprising at least one SMA wire mechanically connected at a first position thereof to the target substrate by at least a first metal plated enchor and being electrically isolated from the target substrate.

The device may comprise a micro-actuator, the micro-actuator comprising a first and a second SMA wire mechanically connected at a first position thereof to the target substrate by a first and second metal plated anchor, the first and second anchor being electrically isolated from the target substrate and from each other, the first and second SMA wire being mechanically and electrically connected to each other at a second position thereof by a metal plated pad, the metal plated pad being mechanically connected to an elastic element for restoring the length of the first and second SMA-wire when not being heated, the metal plated pad being electrically isolated from the elastic element, the first and second metal plated anchor providing electrical contact to the first and second SMA wire for allowing the first and second SMA wire to be heated by Joule-heating when applying a voltage difference over the metal plated anchors.

It is an advantage of embodiments according to the present invention that a micro-actuator having two SMA wires is mechanically very robust in itself because it allows to have a stiffer bias spring, as is the mechanical connection to the substrate. This is especially advantageous as mechanical forces on SMA wires in micro-actuators can be relatively large.

The present invention also relates to a microactuator fabricated at wafer-level and comprising shape memory alloy wires, the micro-actuator comprising a fixed and a movable silicon anchor, mechanically connected to at least one SMA wire actuated by direct joule heating, and at least one silicon spring, serving as bias mechanism for the SMA wires. The mechanical and electrical connections thereby are formed by metal plating, advantageously during the same metal plating process.

The silicon spring serving as bias mechanism may be formed by silicon cantilevers, and the SMA wires may be placed eccentrically onto the silicon cantilevers to allow out-of-plane actuation. It is an advantage of embodiments according to the present invention that a method is provided that allows for batch production of devices containing shape memory alloy wires.

According to one aspect, the present invention relates to a method including deposition of SMA wires onto a substrate that may comprise a silicon wafer, a metal sheet, a polymer film, a multilayer system or combinations thereof, said substrate containing structures serving as bias mechanism for the wires. Mechanical and electrical connection of the wires is provided in a single processing step by plating metal features. The mechanical fixture of SMA wires to the substrate and electrical connection of the SMA wires may be provided by distinct features formed in the same processing step.

The shape memory alloy wires may include nickel-titanium, copper-aluminium-nickel, copper-zinc-aluminium, or some combination thereof.

The shape memory wires may be strained prior integration to a value between 1% and 8%. Suitable plating metals include, without limitation, nickel, copper, tin, silver, gold, and combinations thereof. Suitable plating processes include, without limitations, electroplating and electroless plating. It is also contemplated in a preferred embodiment of the present invention that the SMA wires are first deposited onto a carrier substrate or embedded in polymer and then transferred to the substrate containing the bias mechanism.

According to another aspect, the present invention relates to a shape memory microactuator comprising a fixed and a movable silicon anchor, mechanically connected to two prestrained SMA wires that form a current loop, allowing direct joule heating, and to two Si springs, serving as bias mechanism for the SMA wires. The wires are affixed to the two anchors by plated metal pads.

In a preferred embodiment of the invention, silicon cantilevers serve as bias mechanism and the SMA wires are placed eccentrically onto the silicon cantilevers to allow out-of-plane actuation. An advantage of embodiments of the present invention is that it permits using bulk SMA material in nearly perfect tension, which maximizes the energy efficiency. The integration of SMA wires is performed in a batch fashion, and it allows mass production of the devices. Furthermore, embodiments of the present invention may employ solely plated metal features to form robust mechanical and electrical connections to the wires, so they do not require additional elements such as mechanically-fastened crimps or glues. The integration process is performed in a single process, which results in a simpler process with a sensibly reduced cost for devices fabricated with this method.

Particular and preferred aspects of the invention are set out in the accompanying independent and dependent claims. Features from the dependent claims may be combined with features of the independent claims and with features of other dependent claims as appropriate and not merely as explicitly set out in the claims.

These and other aspects of the invention will be apparent from and elucidated with reference to the embodiment(s) described hereinafter.

### BRIEF DESCRIPTION OF THE DRAWINGS

FIG. 1 contains a perspective view and an enlarged section of a micromachined substrate with integrated SMA wires according to an embodiment of the current invention.

FIG. 2 depicts a process flow for an embodiment of the present invention, referred to as integration of TiNi wires to a silicon structured wafer 1 by electroplating.

FIG. 3 depicts a process flow for an embodiment of the present invention, referred to as integration of TiNi wires to a carrier wafer by embedding the wires in layers of negative photoresist and then to transferring of the SMA wires to silicon structured wafer 1 by electroplating.

FIG. 4 depicts a Joule-heated SMA wire actuator on silicon MEMS fabricated according to an embodiment of the present invention.

FIG. 5 shows a side view of the actuator in its two operational states, the actuator being according to an embodiment of the present invention.

FIG. 6 shows the results of experimental testing of a sample actuator in terms of deflection versus input electrical power, for an actuator according to an embodiment of the present invention.

FIG. 7 shows a SEM picture of a polished cross-section of the electroplated fixture of an SMA wire to a Si surface, as obtained in an embodiment according to the present invention.

FIG. 8 shows the test principle of the destructive tests performed on sample structures to assess the mechanical bond strength between the SMA wires and the substrate and some results of these tests, illustrating features and advantages of embodiments according to the present invention.

The drawings are only schematic and are non-limiting. In the drawings, the size of some of the elements may be exaggerated and not drawn on scale for illustrative purposes.

Any reference signs in the claims shall not be construed as limiting the scope.

In the different drawings, the same reference signs refer to the same or analogous elements.

### DETAILED DESCRIPTION OF ILLUSTRATIVE EMBODIMENTS

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice of the invention.

Furthermore, the terms first, second and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

Moreover, the terms top, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present invention, the only relevant components of the device are A and B.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

In the description provided herein, numerous specific details are set forth. However, it is understood that embodiments of the invention may be practiced without these specific details. In other instances, well-known methods, structures and techniques have not been shown in detail in order not to obscure an understanding of this description.

Where in embodiments of the present invention reference is made to SMA wire, reference is made to a shape memory alloy wire, being an element that exhibits reversible solid state transformation between two characteristic phases: relatively stiff austenite at high temperatures, and relatively ductile martensite at low temperatures.

Where in embodiments of the present invention reference is made to a wire, reference is made to an elongated structure having one dimension substantially larger than the other dimensions. The elongated structure may have any desired cross-section, such as circular, flat, elliptical, or any other shape.

At least some embodiments of the present invention will be described in connection with an array of actuators fabricated from a silicon substrate at wafer level and containing prestrained SMA wires integrated by nickel electroplating. It is contemplated, however, that the described method may be applied to any number of other substrates or devices, and may make use of other materials as would be appreciated by one of ordinary skill in the art.

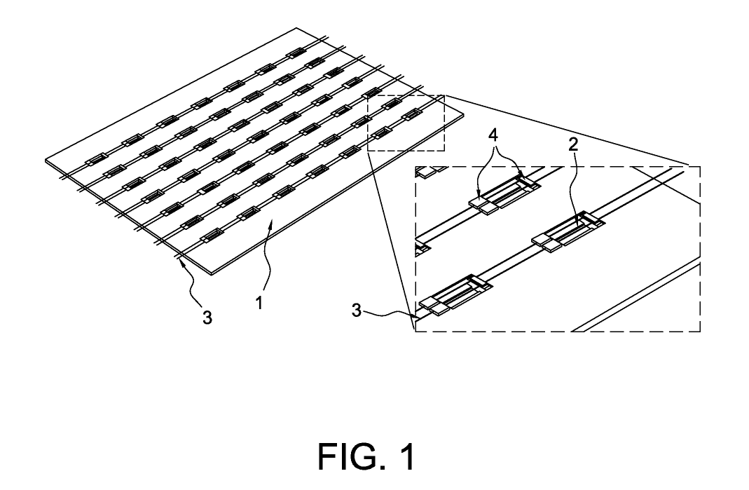

In a first aspect, the present invention relates to a method for manufacturing a device comprising at least one SMA wire as well as a device thus obtained. By way of illustration, embodiments not being limited thereto, an exemplary resulting device is shown in FIG. 1. The method comprises obtaining a target substrate 1, e.g. a target substrate containing structures 2 formed by at least one bias mechanism. The target substrate according to embodiments of the present invention, is a sheet-like substrate and may comprise a silicon wafer, a metal sheet, a polymer film, a multilayer system or combinations thereof. The target substrate may have any suitable thickness, such as for example in the range 0.01 mm to 2 mm. In the manufacturing method, at least one shape memory alloy (SMA) wire 3 is brought into the vicinity of the target substrate, e.g. deposited onto the substrate 1 and mechanically connected to the substrate, e.g. more particularly to structures 2 on the substrate providing at least one bias mechanism. This mechanical connection is obtained by plated metal anchors 4. During the same processing, also an electrical connection point for connecting to the SMA wire is provided. This may be by the same plated metal anchors 4 providing both mechanical connection and electrical connection for connecting to the SMA wire. It is also contemplated for the functions of mechanical anchoring of the SMA wires to the substrate and electrical connection to be performed by distinct plated features that are formed in the same processing step. Such distinct plated features may be distinct in position.

The SMA wire(s) used may have any cross-sectional shape, as described above. According to some embodiments of the present invention, the SMA wires may be pre-strained. Such pre-strained portion may for example be such that its length is 1% to 8% shorter in a heated condition as compared to an unheated condition. The typical materials of which the SMA wires are made may for example be selected from the group consisting of nickel-titanium, nickel-titanium-copper, copper-aluminum-nickel or copper-zinc-aluminum, gold-cadmium, nickel-iron-gallium, etc. The SMA wires may have any suitable shape, such as for example straight wires, coil shaped wires, etc. As will be illustrated below, the SMA wires may be transferred directly to the substrate or may also be transferred using an intermediate substrate.

The plating methods encompassed in embodiments according to the present invention may for example be electroplating, electroless plating, peen plating or mechanical plating or impact plating, etc. Advantageously electroplating or electroless plating may be used. It is an advantage of such methods that thick layers can be deposited at low processing temperatures. The processing temperature advantageously may be sufficiently low so that these are below the transformation temperature of the material, thus allowing avoiding strain recovery during fabrication. When electroless plating is used, the metal deposition is started from a seed layer previously deposited and there is no need to electrically connect all parts of the device. Furthermore, electroless plating nickel may offer better wear and corrosion resistance than electroplated nickel.

Techniques for electroplating or electroless plating as such are known for the person skilled in the art. For the sake of completeness, one example is disclosed below in the first particular embodiment, the invention not being limited thereto. Examples of suitable plating compounds include, but are not limited to, nickel, copper, tin, silver, gold and any combination thereof. Materials may e.g. be selected based on the required oxidation resistance, electric conductivity and biocompatibility. Combination of Cu, Ni and Au is one example of a combination that may be used. According to some embodiments of the present invention, the at least one SMA wire can be completely surrounded by plated metal over at least a part of its length by the metal plating technique. The length over which the plated metal may be provided may for example be over a length in the range 40 μm to 2000 μm, e.g. in the range 200 μm to 1000 μm. The plated molds may have an aspect ratio of 2 to 1. In some examples, nickel was used because of its easy processing at small scales and because of the good results obtained, as well as due to its chemical similarity with the Ti—Ni wire. Further particular examples can be, the use of gold and copper plating on Ti—Ni components, although embodiments are not limited thereto.

According to embodiments of the present invention, the substrate may comprise one or more structures adapted for restoring the wire to its low temperature state. Although advantageous for restoring the SMA wire in its low temperature state, such a structure is not limiting for embodiments of the present invention. Such at least one structure may be referred to as a structure providing a bias mechanism. Such at least one structure providing a bias mechanism may be a bias structure, e.g. an elastic element such as a cantilever, that can provide sufficient force to bring the at least one SMA wire to its original condition. One example is a linear spring allowing in plane motion, machined out of the silicon wafer. In general, any suitable flexure can do the job. In some embodiments, advantageously the complexity of the design process is transferred from the SMA material to the bias spring, which is working in the elastic range and therefore easier to design. Techniques for providing a substrate with a cantilever, an elastic portion or other structure providing a bias mechanism are known to the skilled person.

By way of illustration, standard and optional features will further be described with reference to particular embodiments, other embodiments of the present invention not being limited thereto or thereby.

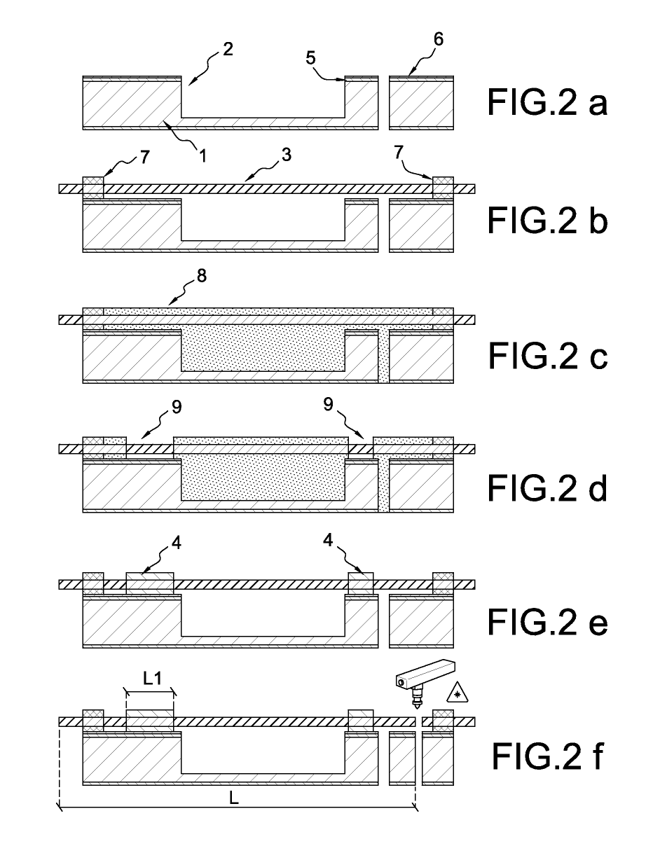

FIG. 2 is a process flow of one particular embodiment of the present invention, referred to as integration of TiNi wires to a silicon structured wafer 1 by electroplating. An array of structures 2 is machined on the target wafer 1, as shown in FIG. 1 and FIG. 2a, each of the structures 2 containing a structure providing a bias mechanism. A thin electrical insulation layer 5 is present on at least one of the two faces of wafer 1, on the side where integration of the SMA wires is to be performed. Preferably, the insulation layer 5 is a silicon dioxide layer thermally grown on the wafer prior the fabrication of structures 2. Thereafter, target wafer 1 is covered with a TiW layer, serving as adhesion layer, and a nickel layer 6, by sputter deposition. It is also contemplated for layer 6 to be formed by other conductive materials or combinations thereof. TiNi wires 3 are transferred to target wafer 1 and held in place by intermediate adhesive anchors 7, which are defined across wafer 1 using a coarse manual curing step (FIG. 2b). Transfer of the wires 3 can be accomplished, without limitations, using a metal frame, automatic placement machines or other suitable methods.

A thick layer of negative photoresist 8 is applied onto the target wafer 1 until it covers the TiNi wires 3 (FIG. 2c). Application of resist 8 may be performed, without embodiments being limited thereto, by spin-coating, screen printing, lamination of dry film resist, or other suitable processes and combination thereof.

Electroplating molds 9 are defined at wafer-level by photo-patterning and curing resist layer 8 (FIG. 2d). Said electroplating molds 9 are defined in locations where mechanical connections between target wafer 1 and TiNi wires 3 or electrical contacts to the TiNi wires 3 are desired. Thereafter, the exposed portions of the SMA wires 3 and the conductive layer 6 on the silicon wafer 1 are activated by suitable acid treatments. In a preferred embodiment, said acid treatments include dipping of the wafer 1 in HF:H₂O.

Silicon-TiNi fixtures 4 are formed on every structure 2 by nickel electroplating. Layer 6 serves as cathode in this electroplating step. In a preferred embodiment, the electroplated fixtures 4 serve also as electrical contacts to the TiNi wires.

In another embodiment of the present invention, the mechanical anchoring and electrical contacting functions may be provided by distinct plated fixtures 4.

Also contemplated is the possibility of forming the fixtures 4 by electroless plating, in which case layer 6 serves as seed layer.

After the electroplating step, resist 8 is stripped (FIG. 2e). Stripping process, compounds and conditions depend on the selection of resist 8, as will be appreciated by one of ordinary skill in the art.

Conductive layer 6 is etched by standard wet or dry processes, or combinations thereof. In one preferred embodiment, the TiW adhesion layer and the conductive Layer 6 are removed with aluminum etchant and H₂O₂, respectively. Thereafter, the wafer 1 and the TiNi wires 3 are diced and the wafer is separated into single chips (FIG. 2f). By removal of the conductive layer 6, the electrical connection formed for electrically connecting to the SMA wire can be electrically insulated from the substrate.

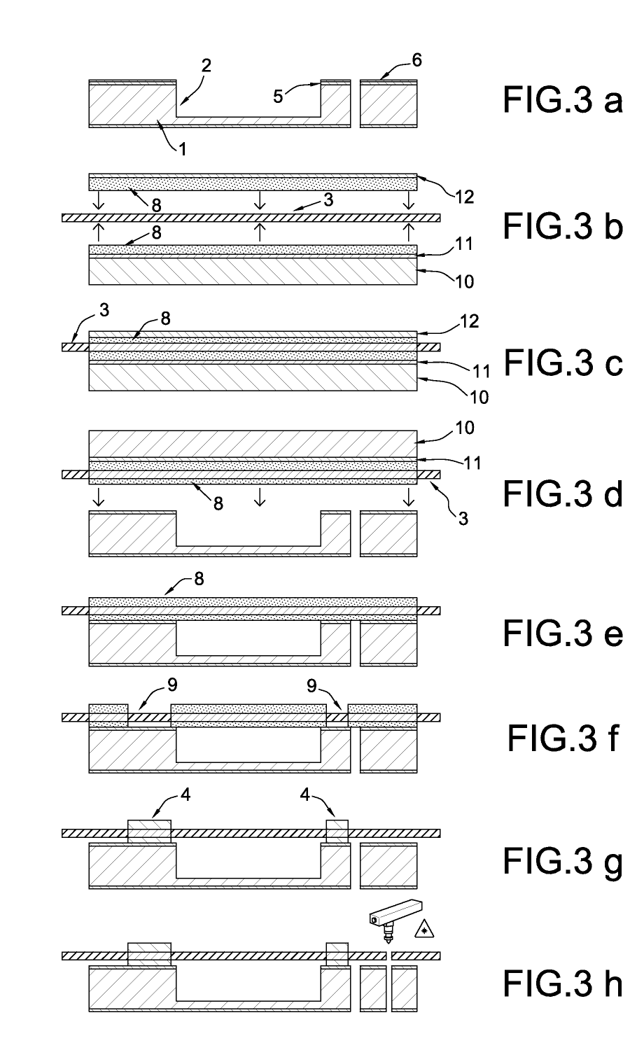

An alternative particular embodiment of the present invention is shown in FIG. 3. The embodiment starts with a target substrate 1 as in FIG. 1, including the array of structures 2 (FIG. 3a) as previously described. Rather than depositing TiNi wires 3 directly onto target substrate 1, TiNi wires 3 are embedded in two layers of negative photoresist 8 (FIG. 3b). Photoresist 8 is applied onto a carrier substrate 10, which may be coated with a sacrificial layer 11. The upper part of photoresist 8, not in contact to carrier wafer 10 or sacrificial layer 11, may be covered with a protective liner 12 (FIG. 3c). The photoresist 8 may be thick photoresist coated onto carrier substrate 10, dry film resist laminated onto carrier substrate 10 or a combination thereof. Upon deposition of SMA wires 3 onto target wafer 1, protective liner 12 is removed, and the part of photoresist 8 not in contact to carrier wafer 10 or sacrificial layer 11 is brought in contact with target wafer 1 on the side where layer 6 has been deposited (FIG. 3d). Thereafter, sacrificial layer 11 is etched away and carrier wafer 10 is removed (FIG. 3e). The following steps can be performed as previously explained, and involve formation of molds 9 (FIG. 3f), plating of metal features 4 to mechanically and electrically integrate SMA wires 3 (FIG. 3g) and dicing of the wafer (FIG. 3h).

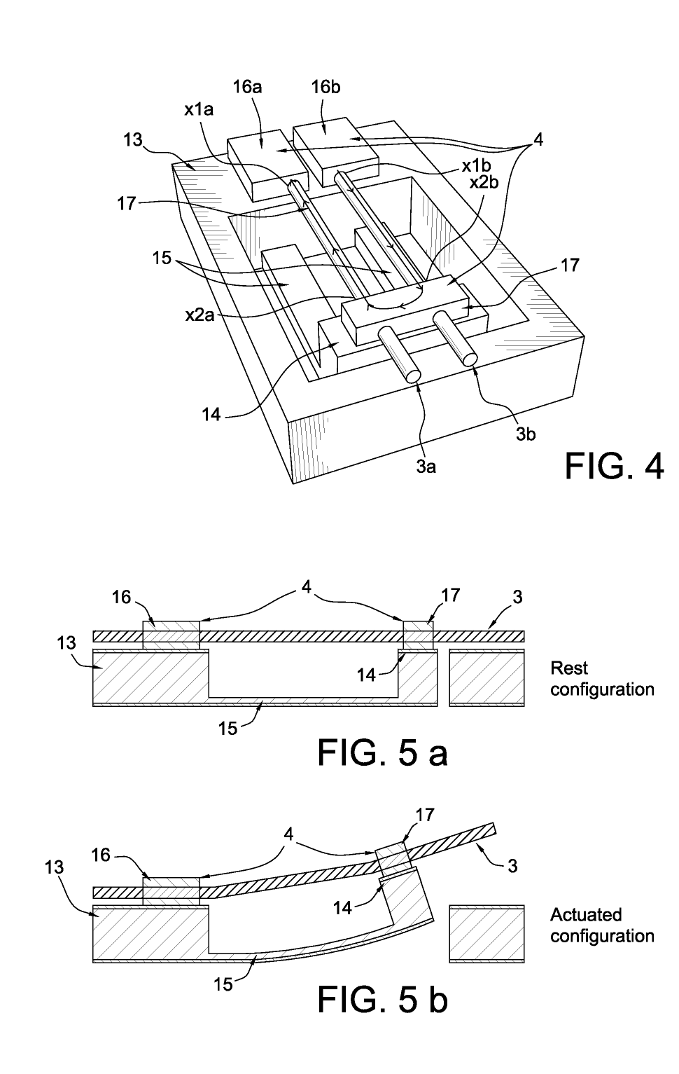

In a particular embodiment of the present invention, a device being or comprising a microactuator also is disclosed. The microactuator thereby comprises prestrained SMA wires, as shown in FIG. 4. The actuator according to an example of the particular embodiment may be fabricated at wafer-level onto a silicon substrate with one of the previously described methods, and comprises a fixed silicon anchor 13 and a movable silicon anchor 14 that are mechanically connected to two silicon cantilevers 15. SMA wires 3a and 3b are first deformed to the desired strain value and then they are mechanically connected to fixed anchor 13 and movable anchor 14 by electroplated metal features 16a, 16b at positions xla and xla. The prestrained SMA wires 3 are placed eccentrically with respect to silicon cantilevers 15 to allow out-of-plane actuation. Electroplated fixtures 16a and 16b on the fixed silicon anchor provide electrical contact pads (also indicated by 16a and 16b) to the SMA wires 3a and 3b. The SMA wires 3a and 3b can form an electrical loop when connected in series with the metal pad 17 formed by electroplated features 17 on the movable silicon anchor 14. The latter is performed at positions x2a and x2b of the SMA wires. When a suitable voltage is applied to electrical contact pads 16, an electric current 17 flows through SMA wires 3 and determines a phase change in the wires by Joule heating. FIG. 5 shows the schematic operational states of the actuator. The metal plated features 16 and 17 can be metal plated using the same process, these metal plated features also being indicated by reference numeral 4. At rest (FIG. 5a) the cantilevers 15 stretch the SMA wires 3. Upon actuation, the SMA wires 3a and 3b tend to return to their memorized shape, thus lifting movable silicon anchor 14. Also contemplated herein is the substitution of silicon cantilevers 15 by silicon springs, to allow in plane actuation, as will be appreciated by one of ordinary skill in the art.

It is intended that all matter contained in the above description or shown in the accompanying drawings shall be interpreted as illustrative only and not limiting. Changes in detail or structure may be made without departing from the spirit of the invention as defined in the appended claims.

### EXAMPLES

An array of actuators according to an embodiment of the present invention shown in FIG. 5 was fabricated from a silicon substrate at wafer scale and tested. The total footprint of each device was 4.5×1.8 mm².

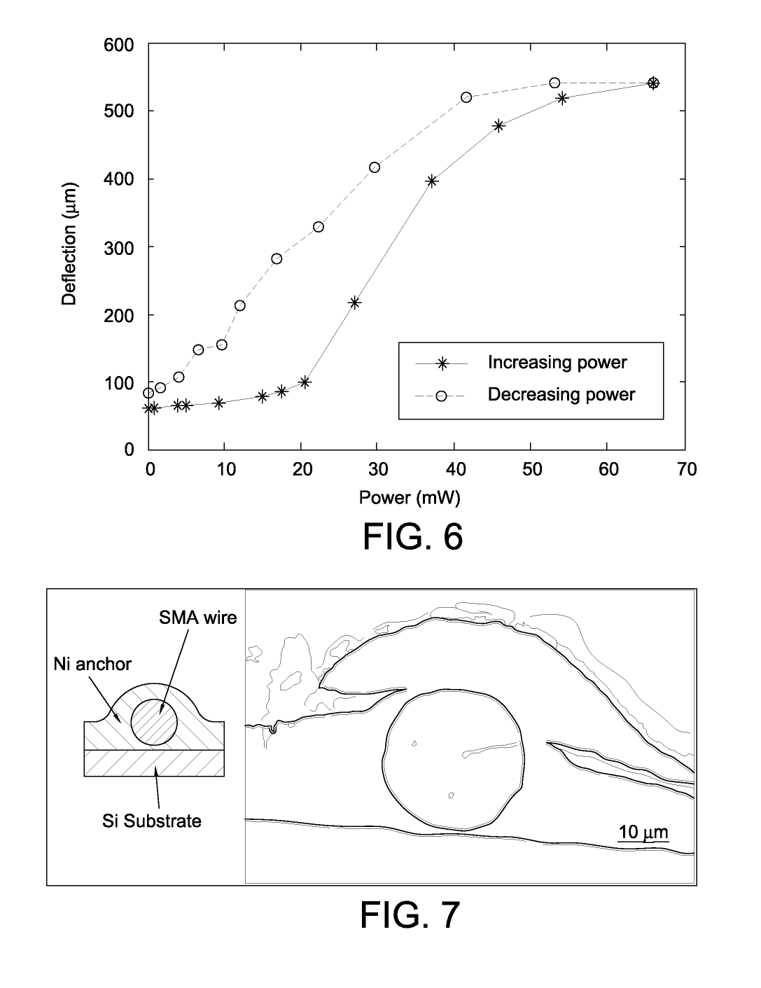

Repeatable actuation was observed, and the actuator featured deflections between 80 μm and 540 μm, thus a net stroke of 460 μm. The actuation current at full deflection was 82 mA, for a corresponding voltage of about 0.8 V, hence a maximum input power below 70 mW. FIG. 6 shows the actuator deflection vs. input power along a complete heating-cooling cycle during testing of a sample.

The bond between the SMA wires and the electroplated nickel on test structures fabricated according to the present invention was investigated by scanning electron microscopy (SEM) and by mechanical testing using a tool for wire bonding testing (Dage PC 2400).

Prior to the SEM, a chip was embedded in polymer for mechanical stability, then a cross-section of the electroplated fixture of an SMA wire to a Si surface was prepared by mechanical polishing. A SEM picture of this cross section is depicted in FIG. 7 and it shows homogeneous plating around the SMA wire, with intimate contact to the nickel and robust mechanical interconnection between the wire 3 and the silicon anchor.

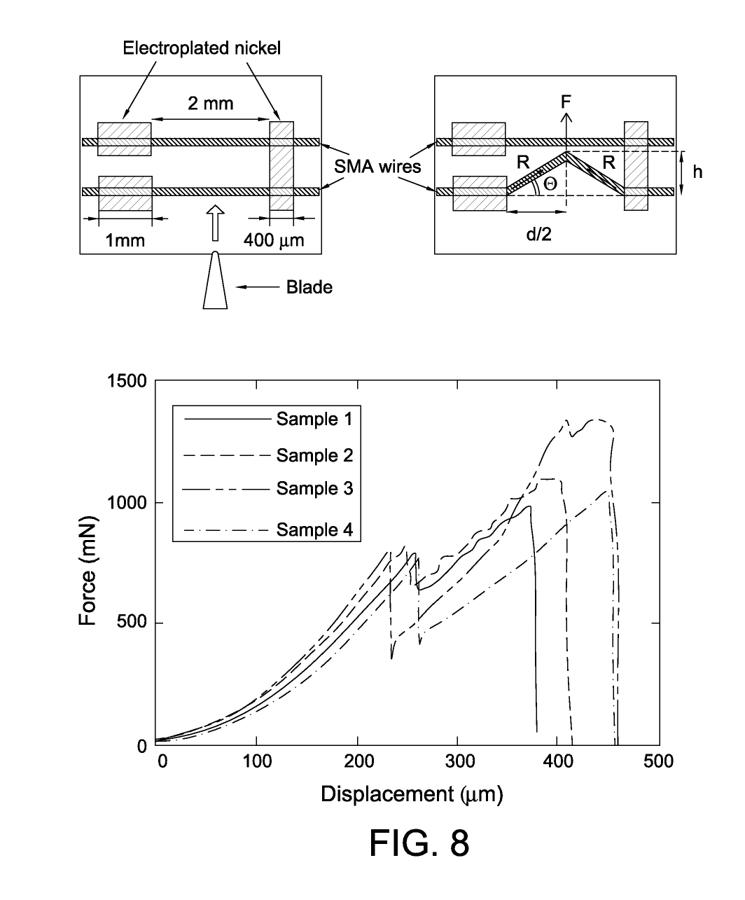

Destructive tests were performed on sample structures using the shear tester. In this set-up a blade was moved perpendicularly to the SMA wires at a constant speed, while the force was recorded. A schematic drawing of the test principle is shown in FIG. 8, along with plots of blade displacement vs. force for different samples, which show the extremely robust mechanical bond between the SMA wires and the silicon substrate achieved by electroplating nickel anchors.

1. A method for producing a device comprising at least one SMA (shape memory alloy) wire capable of changing its length when heated, the method comprising:
providing sheet-like target substrate,
positioning the at least one SMA wire in the vicinity of the target substrate, and
mechanically connecting the at least one SMA wire to the target substrate by a metal plating process and providing, in the same metal plating process, an electrical connection pad to the SMA wire.

2. The method according to claim 1, wherein the metal plating is performed such that the at least one SMA wire is completely surrounded by plated metal over at least a part of its length.

3. The method according to claim 1, wherein the sheet-like target substrate comprises one or more of a silicon wafer, a metal sheet, a polymer film or a multi-layer substrate.

4. The method according to claim 1, wherein the electrical connection pad is electrically separated from the sheet-like target substrate.

5. The method according to claim 1, wherein a mechanical connection obtained by the mechanically connecting and the electrical connection pad are positioned at distinct locations.

6. The method according to claim 1, wherein the metal plating process is an electroplating process and/or the process comprises applying one or more of the group of nickel, copper, thin, silver or gold.

7. The method according to claim 6, wherein the sheet-like target substrate comprises an electrically conductive or semi-conductor material, and wherein the method further comprises
applying an insulating layer on top of the target substrate for electrically separating the SMA wire from the target substrate, and
depositing a conductive layer on top of the insulating layer for providing a seed layer for allowing electroplating.

8. The method according to claim 7, wherein the target substrate is a silicon substrate, and wherein said applying an insulating layer comprises applying a SiO₂ layer on the silicon substrate, and said depositing a conductive layer comprises depositing a nickel layer on top of the SiO₂ layer.

9. The method according to claim 1, wherein the metal plating process is an electroless plating process.

10. The method according to claim 1, wherein the at least one SMA wire is a pre-strained SMA wire.

11. The method according to claim 10, wherein the pre-strained SMA wire is pre-strained such that its length is 1% to 8% shorter in a heated condition as compared to an unheated condition.

12. The method according to claim 1, wherein the at least one SMA wire comprises an alloy selected from the group consisting of nickel-titanium, copper-aluminum-nickel and copper-zinc-aluminum.

13. The method according to claim 1, wherein said positioning of the at least one SMA wire comprises bringing the SMA wire in the vicinity of the target substrate and temporarily holding the SMA wire using an adhesive anchor.

14. The method according to claim 1, wherein said positioning of the at least one SMA wire comprises bringing the SMA wire in the vicinity of a carrier substrate, and thereafter transferring the SMA wire to the target substrate.

15. The method according to claim 1, wherein the device comprises at least a first and a second SMA wire, and wherein the step of mechanically connecting and providing an electrical connection pad is performed by providing two separate electrical contact pads at first positions of the first and second SMA wire, and by providing a single metal pad for interconnecting the first and second SMA wires at second positions thereof, distinct from the first positions.

16. The method according to claim 1, wherein the device to be produced comprises a micro-actuator, the micro-actuator comprising the at least one SMA wire and further comprising an elastic element for restoring the length of the SMA-wire when the SMA wire is not heated, wherein
said providing a target substrate comprises providing a target substrate having at least one elastic element,
said positioning comprises positioning the at least one SMA wire in the vicinity of the elastic element, and
said mechanically connecting and providing an electrical connection pad comprises performing metal plating for mechanically connecting the at least one SMA wire to the target substrate at a first position, and to the elastic element at a second position, different from the first position.

17. The method according to claim 16, wherein said positioning step comprises positioning the SMA wire eccentrically with respect to the elastic element for allowing out-of-plane actuation.

18. The method according to claim 1 for producing a device comprising an array of structures, each comprising at least one SMA wire, wherein:
said positioning comprises the positioning of a plurality of SMA wires in the vicinity of the target substrate, and
said mechanically connecting and providing an electrical connection pad comprises performing metal plating for mechanically connecting each of the plurality of SMA wires at multiple locations to the target substrate simultaneously, and for providing in the same metal plating step a plurality of electrical contact pads to each of the SMA wires, the electrical contact pads being electrically isolated from the target substrate.

19. A device comprising at least one SMA wire capable of changing length when heated, the device comprising:
a sheet-like target substrate;
the at least one SMA wire being mechanically connected to the target substrate by a metal plated anchor and comprising an metal plated electrical connection pad for electrically connecting to the SMA wire.

20. The device according to claim 19 comprising a micro-actuator, the micro-actuator comprising:
a first and a second SMA wire mechanically connected at a first position thereof to the target substrate by a first and second metal plated anchor, the first and second anchor being electrically isolated from the target substrate and from each other;
the first and second SMA wire being mechanically and electrically connected to each other at a second position thereof by a metal plated pad, the metal plated pad being mechanically connected to an elastic element for restoring the length of the first and second SMA-wire when not being heated, the metal plated pad being electrically isolated from the elastic element;
the first and second metal plated anchor providing electrical contact to the first and second SMA wire for allowing the first and second SMA wire to be heated by Joule-heating when applying a voltage difference over the metal plated anchors.
